(19) United States
(12) Patent Application Publication
(10) Pub. No.: US 2014/0144682 A1
(43) Pub. Date: May 29, 2014

(54) SURFACE FINISH FOR CONDUCTIVE FEATURES ON SUBSTRATES

(71) Applicant: RF MICRO DEVICES, INC., Greensboro, NC (US)

(72) Inventors: John August Orlowski, Summerfield, NC (US); Donald Joseph Leahy, Kernersville, NC (US)

(73) Assignee: RF Micro Devices, Inc., Greensboro, NC (US)

(21) Appl. No.: 13/891,888

(22) Filed: May 10, 2013

Related U.S. Application Data
(60) Provisional application No. 61/730,649, filed on Nov. 28, 2012.
(60) Provisional application No. 61/791,849, filed on Mar. 15, 2013.

(51) Int. Cl. H05K 1/09; H05K 3/00

(52) U.S. Cl. CPC H05K 1/09; H05K 3/00
USPC 174/257; 216/13

(57) ABSTRACT

An electronic substrate includes one or more conductive features. In order to preserve the performance and conductivity of the one or more conductive features, the exposed portions of the conductive features are deposited with a protective layer comprising a layer of silver, followed by a layer of gold. By covering the exposed portions of the conductive features of the electronic substrate with the protective layer, oxidation and exposure of the conductive features is prevented, thereby preserving the performance and conductivity of the copper features. Further, during a soldering process, the protective layer is substantially dissolved, thereby allowing the solder to join directly with the underlying conductive features and improving the performance of the electronic substrate.

### RELATED APPLICATIONS

This application claims the benefit of provisional patent application Ser. No. 61/730,649, filed Nov. 28, 2012, and provisional patent application Ser. No. 61/791,849, filed Mar. 15, 2013, the disclosures of which are hereby incorporated by reference in their entirety. The application is also related to the concurrently filed patent application entitled “SURFACE FINISH FOR CONDUCTIVE FEATURES ON SUBSTRATES,” the disclosure of which is hereby incorporated herein by reference in its entirety.

### FIELD OF THE DISCLOSURE

The present disclosure relates to protective finishes for printed circuit boards, and specifically to the use of silver as a protective layer on a printed circuit board.

### BACKGROUND

Printed circuit boards (PCBs) are often used to support and connect electrical components and electronic packages. Generally, a PCB includes a non-conductive substrate for support, and a plurality of conductive features for connecting the electrical components or electronic packages. The conductive features may be any type of conductive structure and may include contact pads, conductive traces, vias, and/or the like. Electrical components such as resistors, capacitors, inductors, bond wires, and integrated circuits (ICs) are mounted to one or more exposed portions of the conductive features by a soldering process. For example, the conductive features may include one or more contact pads connected to one another by one or more conductive traces. An IC circuit (such as a semiconductor die) may be mounted on the one or more conductive pads by the soldering process. Accordingly, one or more circuits are formed on the PCB.

The conductive features of a PCB are often created by a copper etching process, wherein a thin copper sheet is laminated onto the non-conductive substrate and etched to form a connection pattern. The conductive properties and performance characteristics of the conductive features may degrade over time due to oxidation and exposure to the elements. Accordingly, a protective layer is generally deposited onto the one or more conductive features in order to preserve the conductive properties thereof.

FIG. 1A shows a PCB 10 including a non-conductive substrate 12, a plurality of contact pads 14, and a solder mask 16. The non-conductive substrate 12 may be located behind the solder mask 16, and may comprise, for example, a laminate material. The plurality of contact pads 14 may comprise copper, and may be formed by the etching process described above. The plurality of contact pads 14 may be adapted to connect one or more features of an electrical component to one another or to the features of one or more additional electrical components through one or more conductive traces located beneath the solder mask 16 (not shown). Electrical components may be attached to the contact pads 14 using, for example, a soldering process, wherein tin or another soldering material is melted between the conductive features of an electrical component and each one of the plurality of contact pads 14 are cooled to form a mechanical and electrical connection between the two. The solder mask 16 may comprise any non-solderable (i.e., non-wettable) material, and may be adapted to partially cover the contact pads 14 such that an exposed connection pattern is formed that is compatible with a desired electrical component.

FIG. 1B shows a cross-sectional view of the PCB 10 shown in FIG. 1A including the non-conductive substrate 12, the contact pads 14, and the solder mask 16. As shown in FIG. 1B, the contact pads 14 are coupled to the non-conductive substrate 12 and partially covered by the solder mask 16. The portions of the contact pads 14 exposed through the solder mask 16 are the areas of the contact pads 14 available for connection to an electrical component, for example, by a soldering process, as discussed above.

FIG. 1C shows a three-dimensional view of the PCB 10 shown in FIG. 1A including the non-conductive substrate 12, contact pads 14, and the solder mask 16. As shown in FIG. 1C, the contact pads 14 are partially exposed through the solder mask 16. Due to environmental exposure, the contact pads 14 may experience oxidation and degradation of their conductive properties, thereby resulting in greater insertion loss associated with each one of the contact pads 14 and a loss of efficiency for a circuit formed on the PCB 10.

FIG. 2A shows a cross-sectional view of the PCB 10 shown in FIG. 1B, where each one the conductive pads 14 includes a base layer 18, a first protective layer 20A over the portions of the base layer 18 exposed through the soldering mask 16, a second protective layer 20B over the first protective layer 20A, and a third protective layer 20C over the second protective layer 20B (the first protective layer 20A, the second protective layer 20B, and the third protective layer 20C are referred to collectively as the protective layer 20). The protective layer 20 is formed using an ENEPIG (electroless nickel-electroless palladium-immersion gold) process. Accordingly, the first protective layer 20A is electroless nickel, the second protective layer 20B is electroless palladium, and the third protective layer 20C is gold. Although the protective layer 20 prevents oxidation and exposure of the underlying base layer 18, the protective layer 20 may also degrade the conductive properties and performance characteristics of each one of the contact pads 14. For example, when soldering an electrical component to the contact pads 14, the protective layer 20 will melt and mix with tin solder applied to the contact pads 14. The resulting amalgamated tin-nickel-palladium-gold solder joint has less-desirable conductive properties and performance characteristics than that of a tin solder joint alone. Accordingly, the insertion loss associated with each one of the contact pads 14 will increase, thereby degrading the efficiency of a circuit formed on the PCB 10.

FIG. 2B shows a cross-sectional view of the PCB 10 shown in FIG. 1B, where each one of the conductive pads 14 includes the base layer 18, a first protective layer 21 A over the portions of the base layer 18 exposed through the solder mask 16, and a second protective layer 21B over the first protective layer 21A (the first protective layer 21A and the second protective layer 21B are referred to collectively as the protective layer 21). The protective layer 21 is formed using an EPIC (electroless palladium-immersion gold) process. Accordingly, the first protective layer 21A is electroless palladium, and the second protective layer 21 B is gold. Although the protective layer 21 prevents oxidation and exposure of the underlying base layer 18, the protective layer 21 may also degrade the conductive properties and performance characteristics of each one of the contact pads 14. For example, when soldering an electrical component to the contact pads 14, the protective layer 21 will melt and mix with tin solder applied to the contact pads 14. The resulting amalgamated tin-palladium-gold solder joint has less-desirable conductive properties and performance characteristics than that of a tin solder joint alone. Accordingly, the insertion loss associated with each one of the contact pads 14 will increase, thereby degrading the efficiency of a circuit formed on the PCB 10.

### SUMMARY

An electronic substrate includes one or more conductive features. In order to preserve the performance and conductivity of the one or more conductive features, the exposed portions of the conductive features are deposited with a protective layer comprising a layer of silver, followed by a layer of gold. By covering the exposed portions of the conductive features with the protective layer, oxidation and exposure of the conductive features is substantially reduced, thereby preserving the performance and conductivity of the conductive features. Further, during a soldering process, the protective layer is substantially dissolved, thereby allowing the solder to join directly with the underlying conductive features and improving the performance of the printed circuit board.

According to one embodiment, the conductive features are copper formed on the non-conductive substrate using an etching process.

According to one embodiment, the layer of silver is deposited by an immersion process, and is about 0.1 μm to 0.4 μm thick. Additionally, the layer of gold is deposited by an immersion process, and is about 0.05 μm thick or less.

According to one embodiment, the protective layer comprises a layer of silver, followed by an organic or inorganic protective coating. By covering the exposed portions of the conductive features with the protective layer, oxidation and exposure of the conductive features is prevented, thereby preserving the performance and conductivity of the conductive features. Further, during a soldering process, the protective layer is substantially dissolved, thereby allowing the solder to join directly with the underlying conductive features and improving the performance of the electronic substrate.

According to one embodiment, the layer of silver in the protective layer is deposited by an immersion process, and is about 0.1 μm to 0.4 μm thick. Additionally, the organic or inorganic protective coating is about 0.01 μm thick or less.

According to one embodiment, the electronic substrate is for use in a radio frequency (RF) circuit. As is well known in the art, the use of nickel in an RF circuit decreases the performance thereof. By using a protective coating for the conductive features of the electronic substrate that does not include nickel, the performance of the RF circuit is improved.

According to one embodiment, the electronic substrate is for use with flip chip component packages. Using the protective coating on the electronic substrate results in stronger and more reliable solder joints between the electronic substrate and the flip chip component package, thereby improving the performance of the finished electronic substrate.

According to one embodiment, a process for producing a protective layer for the conductive features of an electronic substrate begins by cleaning the electronic substrate in order to remove any contaminants present on the conductive features. The electronic substrate is then rinsed, and the conductive features are micro-etched. The micro-etching removes a small layer of conductive material from the exposed portions of the conductive features. The electronic substrate is then rinsed again, and pre-dipped in an acid solution. A silver deposition process is then performed on the electronic substrate in order to deposit the silver layer over the exposed portions of the conductive features. The electronic substrate is then rinsed and pre-dipped again. A gold deposition process is then performed on the electronic substrate in order to deposit the gold layer over the silver layer. The electronic substrate is then rinsed again and dried.

According to one embodiment, a process for producing a protective layer for the conductive features of an electronic substrate begins by cleaning the electronic substrate in order to remove any contaminants present on the conductive features. The electronic substrate is then rinsed, and the conductive features are micro-etched. The micro-etching removes a small layer of conductive material from the exposed portions of the conductive features. The electronic substrate is then rinsed again, and pre-dipped in an acid solution. A silver deposition process is then performed on the electronic substrate in order to deposit the silver layer over the exposed portions of the conductive features. The electronic substrate is then rinsed again, and an organic or inorganic protective coating is applied to the electronic substrate. The electronic substrate is then dried.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic representation of an electronic substrate.

FIG. 1B is a schematic representation of a side view of the electronic substrate shown in FIG. 1A.

FIG. 1C is a three-dimensional view of the electronic substrate shown in FIG. 1A.

FIG. 2A is a schematic representation of an electronic substrate with a related art protective layer.

FIG. 2B is a schematic representation of an electronic substrate with a related art protective layer.

FIG. 3A is a schematic representation of an electronic substrate with a protective layer according to one embodiment of the present disclosure.

FIG. 3B is a schematic representation of an electronic substrate with a protective layer according to an additional embodiment of the present disclosure.

FIG. 4 is a schematic representation of a flip chip electrical component suitable for attachment to the electronic substrate shown in FIG. 3A and FIG. 3B.

FIG. 5 is a schematic representation showing the alignment of the electronic substrate and the flip chip electrical component according to one embodiment of the present disclosure.

FIG. 6 is a schematic representation showing the flip chip electrical component in contact with the contact pads on a first surface of the electronic substrate.

FIG. 7 is a schematic representation showing the flip chip electrical component mounted to the electronic substrate.

FIG. 8 is a schematic representation of an electrical module including the electronic substrate shown in FIG. 7.

FIG. 9 is a schematic representation of the electrical module shown in FIG. 8 aligned with a PCB.

FIG. 10 is a schematic representation of the electronic module shown in FIG. 8 in contact with the contact pads of the PCB shown in FIG. 9.

FIG. 11 is a schematic representation of the electronic module and PCB shown in FIG. 10 after the electronic module has been soldered to the PCB.

FIG. 12 shows the process for creating the electronic substrate shown in FIG. 3A with the protective layer according to one embodiment of the present disclosure.

FIG. 13 shows a process for creating the electronic substrate shown in FIG. 3B with the protective layer according to an additional embodiment of the present disclosure.

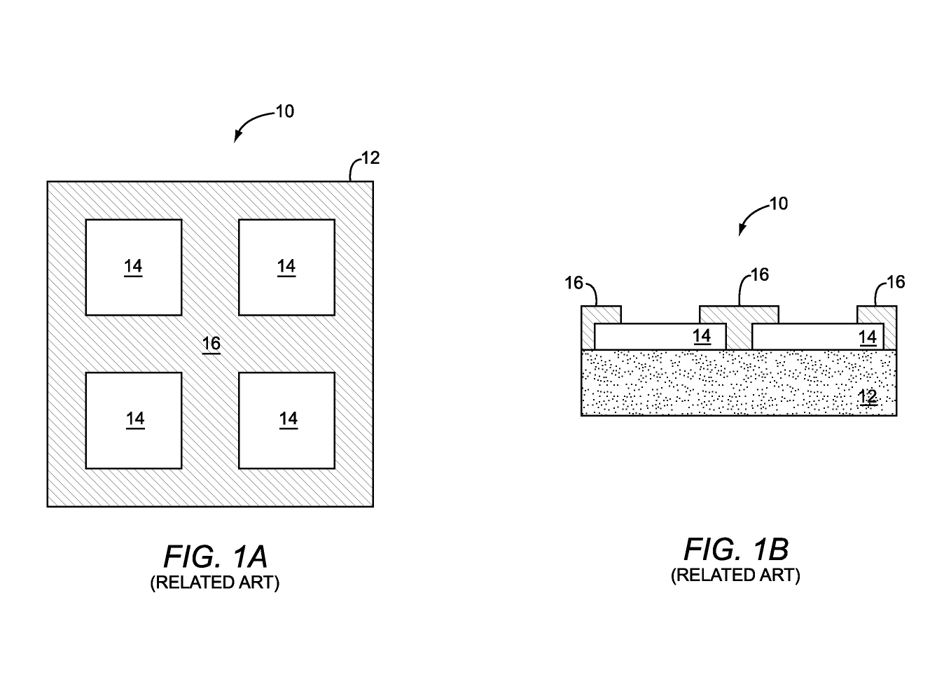

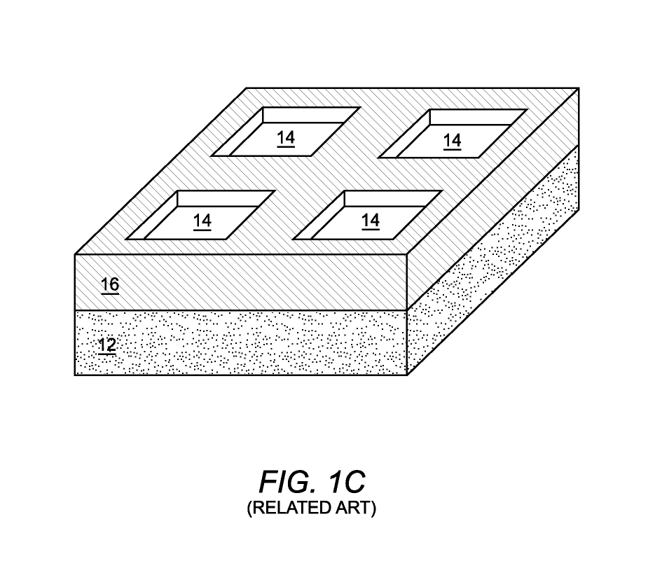

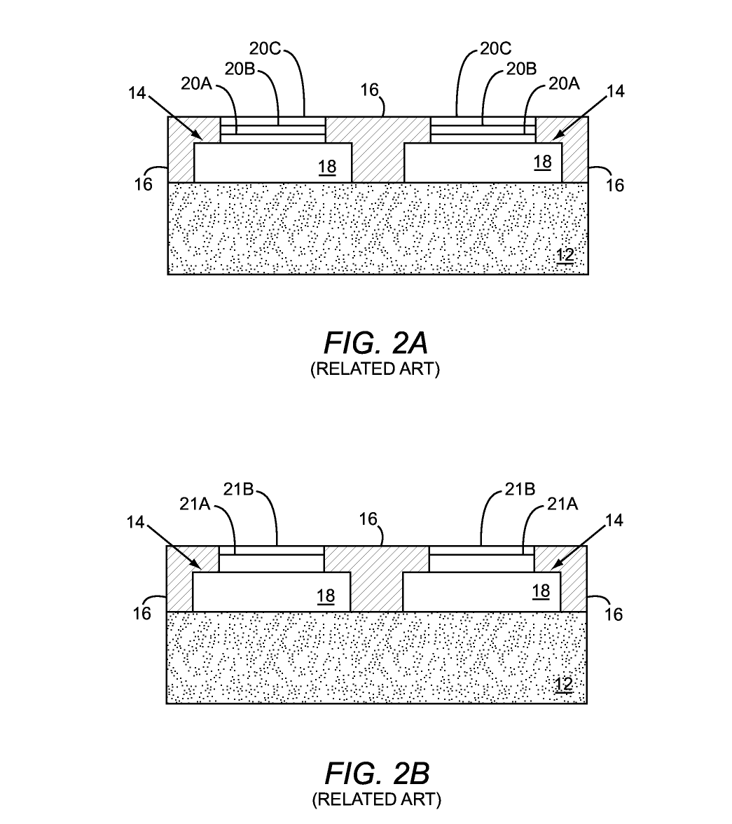

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

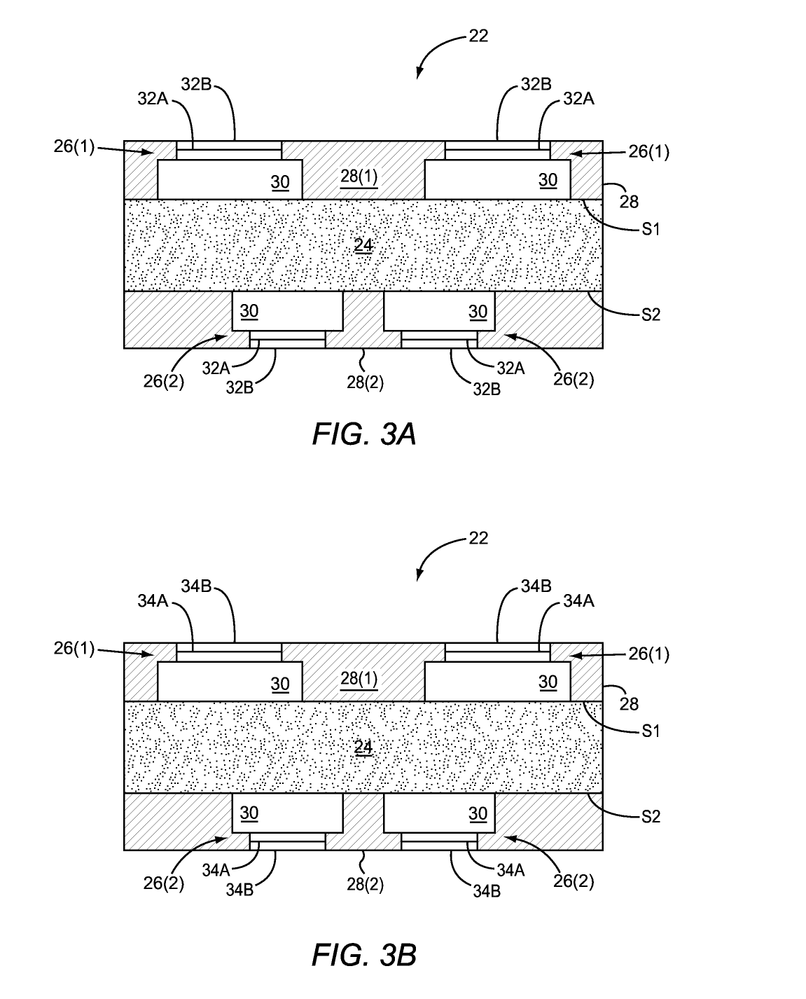

Turning now to FIG. 3A, a cross-sectional view of an electronic substrate 22 is shown according to one embodiment of the present disclosure. According to this embodiment, the electronic substrate 22 includes a non-conductive body 24, a first set of contact pads 26(1) and a second set of contact pads 26(2) (referred to collectively as the contact pads 26), a first solder mask 28(1), and a second solder mask 28(2). Each one of the contact pads 26 may include a base layer 30, a first protective layer 32A over the portions of base layer 30 exposed through the solder mask 28(1) or 28(2), and a second protective layer 32B over the first protective layer 32A (the first protective layer 32A and the second protective layer 32B are referred to collectively as the protective layer 32). The non-conductive body 24 may comprise, for example, a laminate material, a fiber material, a glass material, a ceramic material, and/or the like. The base layer 30 may comprise copper, and may be formed by an etching process, wherein a copper sheet is laminated onto the non-conductive body 24 and etched to form a connection pattern.

The non-conductive body 24 includes a first surface S1 and a second surface S2. In this embodiment, the first surface S1 is on a first side of the non-conductive body 24, while the second surface S2 is on a second side of the non-conductive body 24 opposite the first surface S1. The first side of the non-conductive body 24 with the first surface S1 may be generally referred to as a component side of the non-conductive body 24. The second side of the non-conductive body 24 with the surface S2 may be generally referred to as a connection side of the non-conductive body 24. The contact pads 26 includes a first set of contact pads 26(1) coupled to the non-conductive body 24 on the first surface S1, which is at the component side of the non-conductive body 24. Accordingly, the first set of contact pads 26(1) are exposed at the first surface S1 of the non-conductive body 24. In addition, the contact pads 26 includes a second set of contact pads 26(2) coupled to the non-conductive body 24 on the second surface S2, which is at the connection side of the non-conductive body 24. Accordingly, the second set of contact pads 26(2) are exposed at the second surface S2 of the non-conductive body 24.

The contact pads 26 may be adapted to connect one or more features of an electrical component to one another or to features of one or more additional electronic components through one or more conductive traces located beneath the solder mask 28 (not shown). Electrical components and/or external circuitry may be attached to the contact pads 26 using, for example, a soldering process, wherein tin or another solder material is melted between the conductive features of an electrical component and each one of the contact pads 26 are cooled to form a mechanical and electrical connection between the two. In the embodiment illustrated in FIG. 3A, the first set of contact pads 26(1) are located beneath the solder mask 28 on the first surface S1. The first solder mask 28(1) and the second solder mask 28(2) may comprise any non-solderable (i.e., non-wettable) material, and may be adapted to partially cover the first set of contact pads 26(1) such that an exposed connection pattern is formed that is compatible with a desired electrical component. As explained in further detail below, the electronic substrate 22 may be provided within an electronic module as a mounting apparatus for one or more electronic components. In this case, the electronic module encapsulates the electronic components soldered to the first set of contact pads 26(1) on the first surface S1, which thereby enclose the first surface S1 on the component side. The second set of contact pads 26(2) on the second surface S2 may be externally exposed from the electronic module. In this manner, external circuitry can make connections to the electronic components from the connection side by a soldering process bonding the external circuitry to the second set of contact pads 26(2).

According to one embodiment, the first protective layer 32A is silver, and the second protective layer 32B is gold. The first protective layer 32A may be applied by a silver deposition process, and be about 0.1 μm to 0.4 μm thick. The second protective layer 32B may be deposited by a gold deposition process, and be about 0.05 μm thick or less. By using a silver-gold protective layer 32, oxidation and exposure of the underlying base layer 30 is prevented, thereby maintaining the conductive properties and performance characteristics of the contact pads 26. More specifically, the first protective layer 32A of silver provides a good barrier so that copper in the base layer 30 does not migrate to a surface of the contact pad 26 and cause oxidation. The second protective layer 32B of gold further inhibits copper migration to the surface of the contact pad. Further, the silver-gold protective layer 32 does not significantly affect the conductive properties or the performance characteristics of the contact pads 26. Accordingly, the insertion loss associated with each one of the contact pads 26 is reduced compared to a contact pad using a traditional protective coating, thereby increasing the efficiency of a circuit formed on the electronic substrate 22.

According to one embodiment, the first protective layer 32A of silver is deposited by an immersion process, and the second protective layer 32B of gold is deposited by an immersion gold process. However, any chemical deposition process may be used for applying the first protective layer 32A and the second protective layer 32B without departing from the principles of the present disclosure, including but not limited to autocatalytic or electroless processes.

According to one embodiment, the electronic substrate 22 shown in FIG. 3A is for use with RF signals. Because the protective layer 32 does not contain nickel, the performance of an RF circuit formed on the electronic substrate 22 is improved.

FIG. 3B shows a cross-sectional view of an electronic substrate 22 according to an additional embodiment of the present disclosure. According to this embodiment, the electronic substrate 22 includes the non-conductive body 24, the contact pads 26, the first solder mask 28(1), and the second solder mask 28(2). Each one of the contact pads 26 may include a base layer 30, a first protective layer 34A over the portions of the base layer 30 exposed through the solder mask 28(1) or 28(2), and a second protective layer 34B over the first protective layer 34A (the first protective layer 34A and the second protective layer 34B are referred to collectively as the protective layer 34). As in the embodiment described above in FIG. 3A, the first set of contact pads 26(1) in FIG. 3B are coupled to the non-conductive body 24 on the first surface S1 and the second set of contact pads 26(2) in FIG. 3B are coupled to the non-conductive body 24 on the second surface S2.

According to one embodiment, the first protective layer 34A is silver, and the second protective layer 34B is an organic or inorganic protective coating. The first protective layer 34A may be applied by a silver deposition process, and be about 0.1 μm to 0.5 μm thick. The second protective layer 34B may be about 0.01 μm thick or less. By using silver and an organic or inorganic protective coating to form the protective layer 34, oxidation and exposure of the underlying base layer 30 is prevented, thereby maintaining the conductive properties and performance characteristics of the contact pads 26. More specifically, the first protective layer 34A of silver provides a good barrier so that copper in the base layer 30 does not migrate to a surface of the contact pad 26 and cause oxidation. The second protective layer 34B provides a barrier layer for the first protective layer 34A of silver which inhibits oxidation of the silver layer. Further, the silver and organic or inorganic protective coating that form the protective layer 34 do not significantly affect the conductive properties or performance characteristics of the contact pads 26. Accordingly, the insertion loss associated with each one of the contact pads 26 is reduced compared to a contact pad using a traditional protective coating, thereby increasing the efficiency of a circuit formed on the electronic substrate 22.

According to one embodiment, the first protective layer 34A of silver is deposited by an immersion process. However, any chemical deposition process may be used for applying the first protective layer 34A without departing from the principles of the present disclosure, including but not limited to autocatalytic or electroless processes.

According to one embodiment, the electronic substrate 22 shown in FIG. 3B is for use with RF signals. Because the protective layer 34 does not contain nickel, the performance of an RF circuit formed on the electronic substrate 22 is improved.

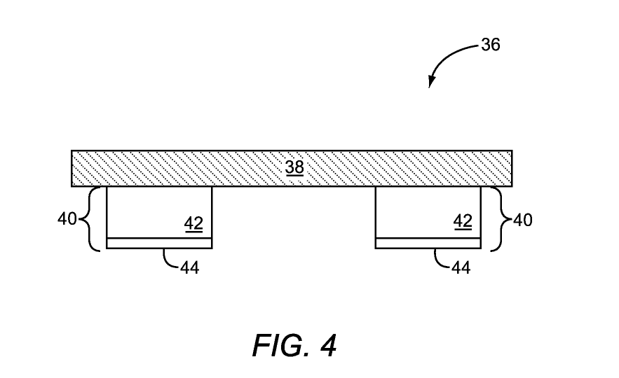

With reference to FIGS. 4-8, a process for attaching an integrated circuit (IC) component to the electronic substrate 22 shown in FIG. 3A is graphically illustrated. First, an IC component is provided for attachment to the first surface S1 of the electronic substrate 22. FIG. 4 shows an exemplary flip chip electronic component 36 suitable for mounting on the electronic substrate 22 shown in FIGS. 3A and 3B. The flip chip electronic component 36 may include a die 38 and one or more conductive pillars 40. Each one of the conductive pillars 40 may include a base layer 42 and a solder layer 44. According to one embodiment, the base layer 42 is comprised of copper, and the solder layer 44 is comprised of tin.

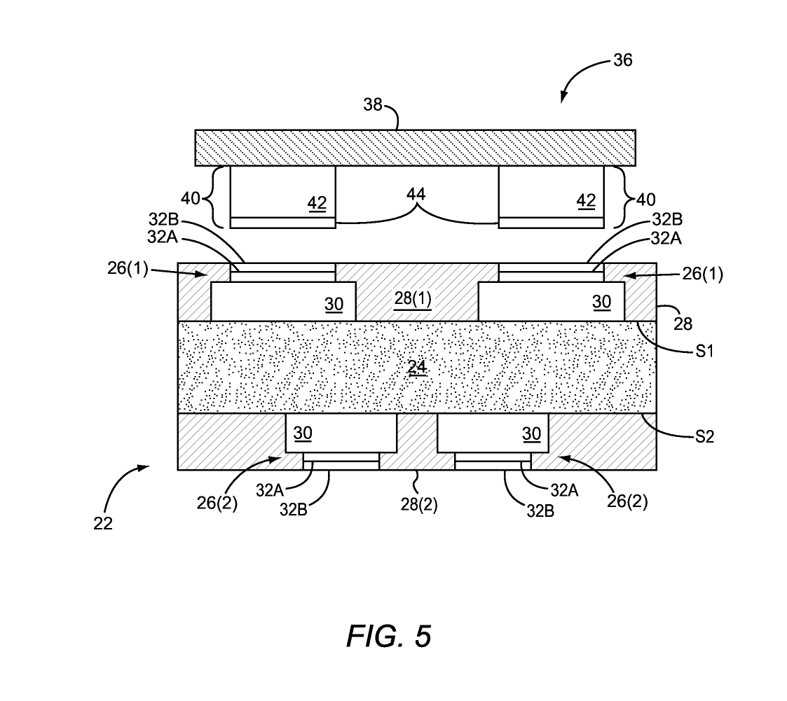

Next, the electronic substrate 22 and the flip chip electronic component 36 are aligned. FIG. 5 shows a cross-sectional view of the electronic substrate 22 shown in FIG. 3A further including the flip chip electronic component 36 for attachment to the first surface S1 of the electronic substrate 22. As shown in FIG. 4, the conductive pillars 40 of the flip chip electronic component 36 are aligned with the first set of contact pads 26(1) of the electronic substrate 22.

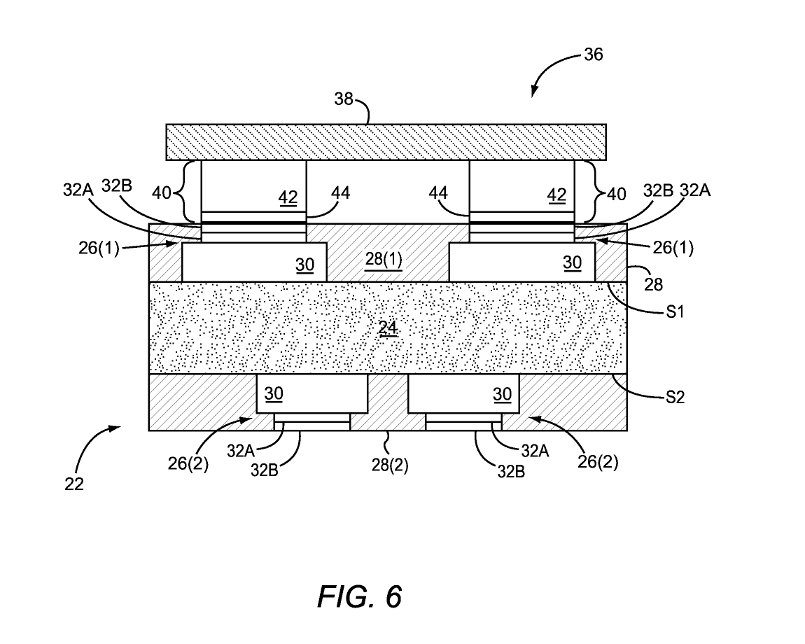

The conductive pillars 40 of the flip chip electronic component 36 are then placed in physical contact with the first set of contact pads 26(1) of the electronic substrate 22. FIG. 6 shows a cross-sectional view of the electronic substrate 22 shown in FIG. 5, wherein the conductive pillars 40 of the flip chip electronic component 36 are in contact with the first set of contact pads 26(1) of the electronic substrate 22. In particular, the solder layer 44 of the conductive pillars 40 on the flip chip electronic component 36 contact the second protective layer 32B of the first set of contact pads 26(1) on the electronic substrate 22.

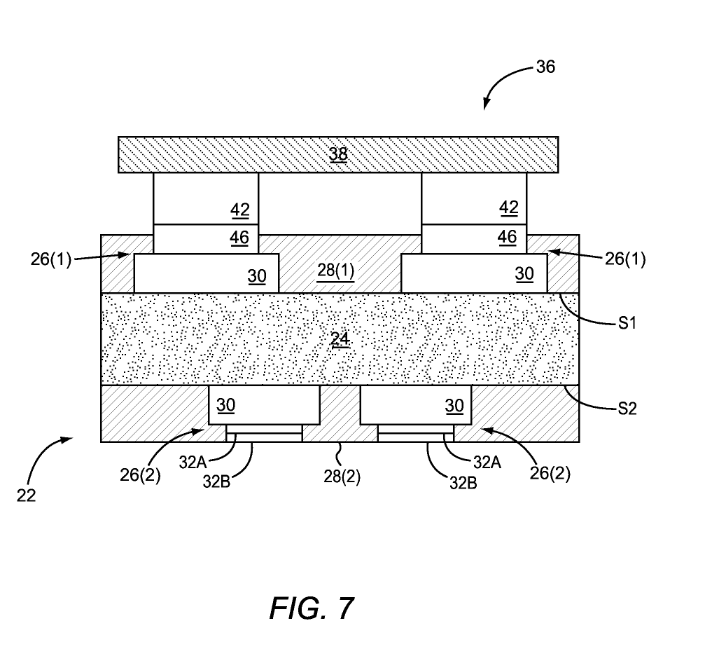

A soldering process is then performed in order to electrically and physically couple the flip chip electronic component 36 and the electronic substrate 22. FIG. 7 shows a cross-sectional view of the electronic substrate 22 shown in FIG. 6, wherein the conductive pillars 40 of the flip chip electronic component 36 are connected to the first set of contact pads 26(1) of the electronic substrate 22 through one or more solder joints 46. According to one embodiment, the flip chip electronic component 36 is attached to the electronic substrate 22 using a soldering process, wherein the conductive pillars 40 of the flip chip electronic component 36 and the first set of contact pads 26(1) of the electronic substrate 22 are heated such that the soldering layer 44 and the protective layer 32 reflow and melt together, then are cooled to form the one or more solder joints 46. During the soldering process, the protective layer 32 is substantially dissolved. The resulting solder joints 46 are formed of an amalgamated tin-silver-gold. According to one embodiment, the base layer 30 of the contact pads 26 is copper. The resultant connections between the copper base layer 30 and the amalgamated tin-silver-gold solder joints 46 have desirable conductive properties and performance characteristics, thereby contributing to the efficiency of a circuit formed on the electronic substrate 22.

Although FIG. 7 shows the electronic substrate 22 attached to a flip chip electronic component 36, any electronic component including any packaging type may be used without departing from the principles of the present disclosure. For example, the electronic substrate 22 may be attached to a bumped die component, a ball grid array component, a small outline integrated circuit, etc.

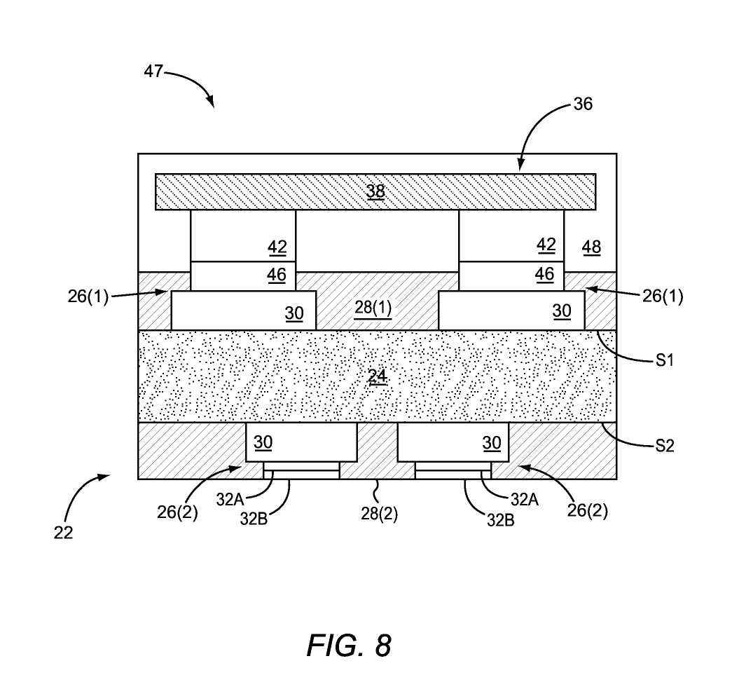

Finally, an over-mold layer is provided over the first surface S1 of the electronic substrate 22 in order to stabilize the flip chip electronic component 36. FIG. 8 shows a cross-sectional view of an electronic module 47 including the flip chip electronic component 36 soldered to the electronic substrate 22. An over-mold layer 48 may be provided to add support and rigidity to the electronic substrate 22, as well as to stabilize the flip chip electronic component 36. Accordingly, the electronic substrate 22 and attached components are protected. The electronic substrate 22 illustrated in FIG. 8 is provided as a mounting structure for electronic components in the in the electronic module 47. The over-mold layer 48 may be formed from a dielectric material such as silicon oxide. As a result, the over-mold layer 48 may electromagnetically isolate the flip chip electronic component 36. An electromagnetic shield (not shown) may be formed on the surface on top of the over-mold layer 48 in order to further isolate the flip chip electronic component 36.

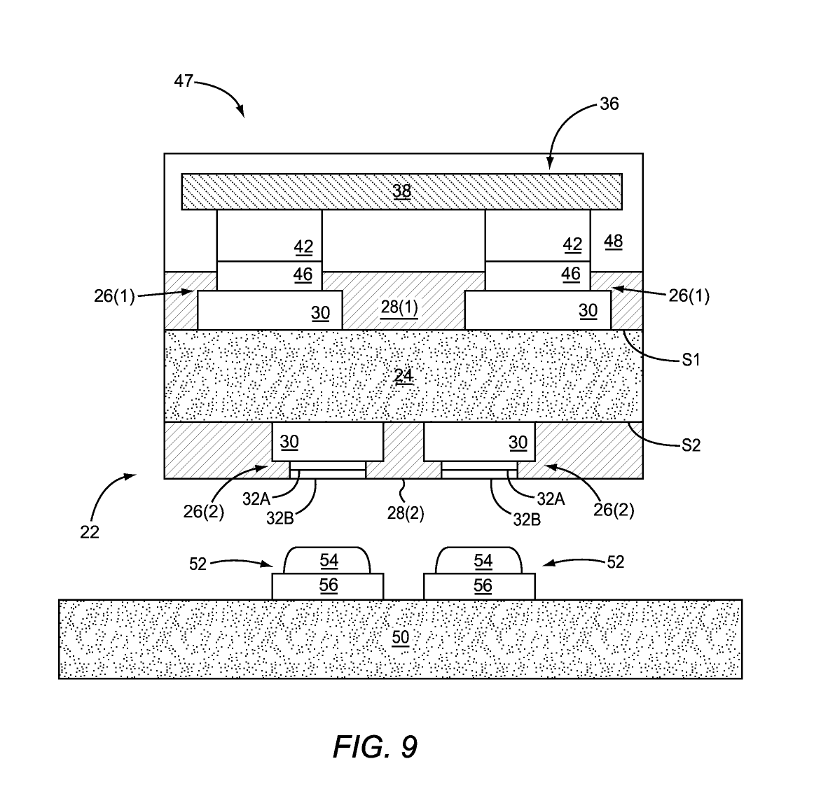

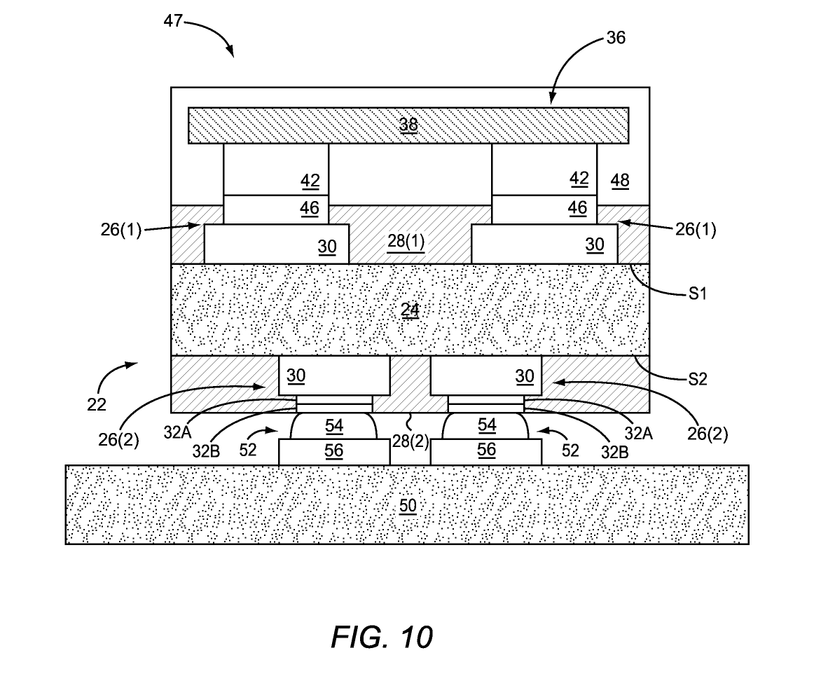

With reference to FIGS. 9-11, a process for attaching the electronic module 47 shown in FIG. 8 to a printed circuit board (PCB) 50 is graphically illustrated. The PCB 50 may be configured to mount various electronic modules that enclose electronic components of different kinds. For example, the PCB 50 may be configured to mount and connect various electronic modules in order to provide a radio frequency (RF) transceiver. In one embodiment, an IC formed in the die 38 of the flip chip electrical component 36 is a power amplifier configured to amplify an RF signal. The electronic module 47 may be mounted on the PCB 50 so that the flip chip electronic component 36 is part of the RF transceiver.

FIG. 9 shows the electronic module 47 shown in FIG. 8 and the PCB 50. As shown in FIG. 9, the second set of contact pads 26(2) on the second surface S2 of the electronic substrate 22 are externally exposed. In this manner, external connections can be made to the flip chip electronic component 36 and other circuitry within the electronic module 47 from the connection side of the non-conductive body 24. The electronic module 47 and the PCB 50 are aligned so that the second set of contact pads 26(2) are in alignment with contact pads 52 on the surface of the PCB 50.

FIG. 10 shows a cross-sectional view of the electronic module 47 and the PCB 50 illustrated in FIG. 9, wherein the second set of contact pads 26(2) are placed in contact with the contact pads 52 of the PCB 50. In particular, a solder layer 56 of the contact pads 52 of the PCB 50 is in contact with the second protective layer 32B of the second set of contact pads 26(2) of the electronic module 47. A soldering process is then preformed in order to electrically and physically couple the electronic module 47 and the PCB 50.

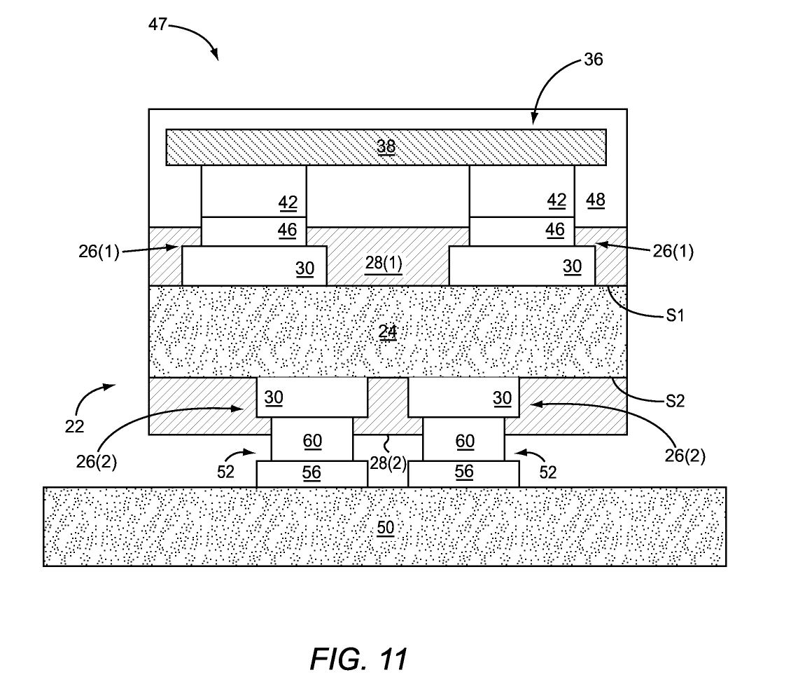

FIG. 11 shows a cross-sectional view of the electronic module 47 and the PCB 50 shown in FIG. 10, wherein the second set of contact pads 26(2) of the electronic module 47 are connected to the contact pads 52 of the PCB 50 through one or more solder joints 60. According to one embodiment, the electronic module 47 is attached to the PCB 50 using a soldering process, wherein the second set of contact pads 26(2) of the electronic module 47 and the contact pads 52 of the PCB 50 are heated such that the solder layer 56 and the protective layer 32 reflow and melt together, then are cooled to form the one or more solder joints 60. During the soldering process, the protective layer 32 is substantially dissolved. The resulting solder joints 60 are formed of an amalgamated tin-silver-gold. According to one embodiment, the base layer 30 of the second set of contact pads 26(2) is copper. The resultant connections between the copper base layer 30 and the amalgamated tin-silver-gold solder joints 60 have desirable conductive properties and performance characteristics, thereby contributing to the efficiency of the IC in the electronic module 47.

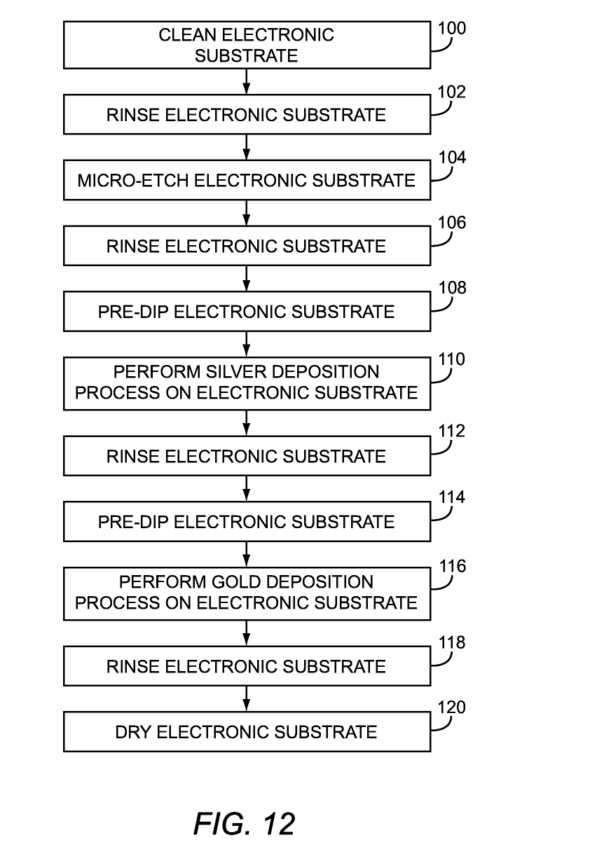

FIG. 12 illustrates a process for forming the protective layer 32 shown in FIG. 3A. First, the electronic substrate 22 is cleaned (step 100). According to one embodiment, the electronic substrate 22 is soaked in an acid cleaner. Next, the electronic substrate 22 is rinsed (step 102) with water. The electronic substrate 22 is then chemically micro-etched (step 104). This may include soaking the electronic substrate 22 in an acid solution in order to etch a small amount of conductive material from the exposed portions of the base layer 30. The electronic substrate 22 is then rinsed again (step 106), and pre-dipped (step 108) in preparation for the silver deposition process (step 110). The pre-dipping may comprise dipping the electronic substrate 22 into an acidic solution in order to remove any water from the electronic substrate 22 as well as to prepare the electronic substrate 22 for the silver deposition process (step 110). The silver deposition process (step 110) may comprise an immersion process, in which the electronic substrate 22 is soaked or dipped in a silver bath. As the electronic substrate 22 is exposed to the silver bath, conductive material from the exposed portions of the base layer 30 is slowly dissolved and replaced with silver in order to form the first protective layer 32A of silver over the base layer 30. The electronic substrate 22 is then rinsed again (step 112), and pre-dipped (step 114) in preparation for the gold deposition process (step 116). The gold deposition process (step 116) may comprise an immersion process, in which the electronic substrate 22 is soaked or dipped in a gold bath. As the electronic substrate 22 is exposed to the gold bath, the first protective layer 32A of silver over the base layer 30 is plated with the second protective layer 32B of gold. The electronic substrate 22 is then rinsed (step 118) and dried (step 120). The resulting protective layer 32 maintains the conductive properties and performance characteristics of the contact pads 26, thereby contributing to the efficiency of a circuit formed on the electronic substrate 22.

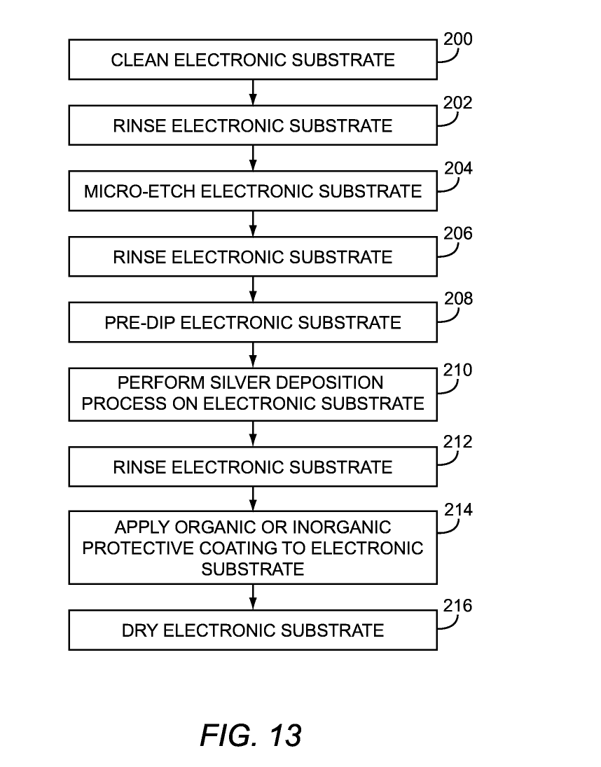

FIG. 13 illustrates a process for forming the protective layer 34 shown in FIG. 3B. First, the electronic substrate 22 is cleaned (step 200). According to one embodiment, the electronic substrate 22 is soaked in an acid cleaner. Next, the electronic substrate 22 is rinsed (step 202) with water. The electronic substrate 22 is then chemically micro-etched (step 204). This may include soaking the electronic substrate 22 in an acid solution in order to etch a small amount of conductive material from the exposed portions of the base layer 30. The electronic substrate 22 is then rinsed again (step 206), and pre-dipped (step 208) in preparation for the silver deposition process (step 210). The pre-dipping may comprise dipping the electronic substrate 22 into an acidic solution in order to remove any water from the electronic substrate 22 as well as to prepare the electronic substrate 22 for the silver deposition process (step 210). The silver deposition process (step 210) may comprise an immersion process, in which the electronic substrate 22 is soaked or dipped in a silver bath. As the electronic substrate 22 is exposed to the silver bath, conductive material from the exposed portions of the base layer 30 is slowly dissolved and replaced with silver in order to form the first protective layer 34A of silver over the base layer 30. The electronic substrate 22 is then rinsed again (step 212), and the second protective layer 34B of organic or inorganic protective coating is applied (step 214). The organic or inorganic protective coating may be sprayed on, or the electronic substrate 22 may be dipped in a solution to form the second protective layer 34B. Finally, the electronic substrate 22 is dried (step 216). The resulting protective layer 34 maintains the conductive properties and performance characteristics of the contact pads 26, thereby contributing to the efficiency of a circuit formed on the electronic substrate 22.

The immersion processes described above use a chemical displacement reaction in which a metal from an aqueous solution of a metallic salt replaces a metal in a metallic base. Alternatively and/or additionally autocatalytic or electroless processes that deposit a metal from an aqueous solution of a metallic salt may be used. While electroplating can be used to provide all or some of the protective layers described above, electroplating generally requires busing which increases the amount of space required to form connections. Using a chemical based deposition process avoids the use of busing and has been shown to reduce connection points by 100 μm to 200 μm. Nonetheless, the immersion silver process described above in FIGS. 12 and 13 could be replaced with an electroless silver deposition process. Other chemical silver deposition processes, such as an autocatalytic silver deposition process, may also be utilized. Similarly, the immersion gold process described above in FIG. 12 can be replaced with an electroless gold deposition process. Other chemical gold deposition processes, such as an autocatalytic gold deposition process, may also be utilized. The preparation procedures described above may also be different based on the chemical processes used to form the protective layers described above, as will be appreciated by those of ordinary skill in the art.

Those skilled in the art will recognize improvements and modifications to the preferred embodiments of the present disclosure. All such improvements and modifications are considered within the scope of the concepts disclosed herein and the claims that follow.

What is claimed is:

1. An electronic substrate comprising:
a non-conductive body;
a plurality of conductive features coupled to the non-conductive body, each one of the plurality of conductive features comprising a base layer and a protective layer, wherein the protective layer comprises a layer of silver over the exposed portions of the base layer and a layer of gold over the layer of silver.

2. The electronic substrate of claim 1 wherein the layer of silver is applied by a chemical deposition process.

3. The electronic substrate of claim 2 wherein the layer of silver is applied by an immersion silver process.

4. The electronic substrate of claim 2 wherein the layer of silver is approximately 0.1 μm to 0.4 μm thick.

5. The electronic substrate of claim 1 wherein the layer of gold is applied by an immersion gold process.

6. The electronic substrate of claim 5 wherein the layer of gold is approximately 0.05 μm thick or less.

7. The electronic substrate of claim 1 wherein the protective layer is adapted to substantially dissolve during a soldering process.

8. The electronic substrate of claim 1 wherein the electronic substrate is adapted for use with flip chip electronic component packages.

9. The electronic substrate of claim 1 wherein the electronic substrate is adapted for use in a radio frequency (RF) circuit.

10. The electronic substrate of claim 1 wherein the plurality of conductive features comprise contact pads adapted to connect to one or more electrical components.

11. The electronic substrate of claim 1 wherein the electronic substrate is a printed circuit board (PCB).

12. An electronic substrate comprising:
a non-conductive body;
a plurality of conductive features coupled to the non-conductive body, each one of the plurality of conductive features comprising a base layer and a protective layer, wherein the protective layer comprises a layer of silver over the exposed portions of the base layer and an organic or inorganic protective coating over the layer of silver.

13. The electronic substrate of claim 12 wherein the layer of silver is applied by a chemical deposition process.

14. The electronic substrate of claim 13 wherein the layer of silver is applied by an immersion silver process.

15. The electronic substrate of claim 13 wherein the layer of silver is approximately 0.1 μm to 0.4 μm thick.

16. The electronic substrate of claim 12 wherein the organic or inorganic protective coating is approximately 0.01 μm thick or less.

17. The electronic substrate of claim 12 wherein the protective layer is adapted to substantially dissolve during a soldering process.

18. The electronic substrate of claim 12 wherein the electronic substrate is adapted for use with flip chip electronic component packages.

19. The electronic substrate of claim 12 wherein the electronic substrate is adapted for use in an RF circuit.

20. The electronic substrate of claim 12 wherein the plurality of conductive features comprise contact pads adapted to connect to one or more electrical components.

21. The electronic substrate of claim 12 wherein the electronic substrate is a printed circuit board (PCB).

22. A process for applying a protective finish to an electronic substrate comprising:
preparing the electronic substrate for a silver deposition process;
performing a silver deposition process on the electronic substrate;
preparing the electronic substrate for a gold deposition process; and
performing a gold deposition process on the electronic substrate.

23. The process of claim 22 wherein preparing the electronic substrate for a silver deposition process comprises:
cleaning the electronic substrate;
rinsing the electronic substrate;
micro-etching the electronic substrate;
rinsing the electronic substrate; and
pre-dipping the electronic substrate in an acid solution.

24. The process of claim 22 wherein preparing the electronic substrate for a gold deposition process comprises rinsing the electronic substrate and pre-dipping the electronic substrate in an acid solution.

25. A process for applying a protective finish to an electronic substrate comprising:
preparing the electronic substrate for a silver deposition process;
performing a silver deposition process on the electronic substrate;
preparing the electronic substrate for the application of an organic or inorganic protective coating; and
applying the organic or inorganic protective coating to the electronic substrate.

26. The process of claim 25, wherein preparing the electronic substrate for a silver deposition process comprises:
cleaning the electronic substrate;
rinsing the electronic substrate;
micro-etching the electronic substrate;
rinsing the electronic substrate; and
pre-dipping the electronic substrate in an acid solution.

27. The process of claim 25 wherein preparing the electronic substrate for the application of an organic or inorganic protective coating comprises rinsing the electronic substrate.
